(19) United States
(12) Patent Application Publication
(10) Pub. No.: US 2008/0079090 A1
(43) Pub. Date: Apr. 3, 2008

(54) Semiconductor device including recessed spherical silicide contact part and method of manufacturing the same

(75) Inventors: Hong-kyu Hwang, Hwaseong-si (KR); Dae-ik Kim, Yongin-si (KR); Seung-beom Kim, Suwon-si (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 11/900,772

(22) Filed: Sep. 13, 2007

(30) Foreign Application Priority Data
Oct. 2, 2006 (KR) 10-2006-0097153

(51) Int. Cl. H01L 29/78; H01L 21/336

(52) U.S. Cl. 257/384; 438/294; 257/E29.255; 257/E21.409

(57) ABSTRACT

A semiconductor device and fabrication method thereof protect an overgrown metal silicide layer from external damage. The semiconductor device includes: isolation regions formed on a substrate; source/drain regions in the substrate between the isolation regions; a first interlayer insulating film on the substrate, the isolation regions and the source/drain regions; contact pads vertically penetrating the first interlayer insulating film and electrically connected to the source/drain regions; a second interlayer insulating film on the first interlayer insulating film and the contact pads; a metal silicide region selectively formed on the contact pads at a vertical position that is lower than an upper surface of the first interlayer insulating film; and a contact plug vertically penetrating the second interlayer insulating film and electrically connected to the metal silicide region.

### CROSS REFERENCE TO RELATED APPLICATION

This application claims priority from Korean Patent Application No. 10-2006-0097153 filed on Oct. 2, 2006 in the Korean Intellectual Property Office, the disclosure of which is incorporated herein by reference in its entirety.

### BACKGROUND OF THE INVENTION

1. Field of the Invention

Embodiments of the present disclosure relate to a contact of a semiconductor device and, more particularly, to a semiconductor device, in which a silicide region formed on an upper end portion of a contact is lowered and a contact area is widened to protect an overgrown metal silicide region from external physical and chemical damage, and a method of manufacturing the same.

2. Description of the Related Art

As semiconductor devices continue to become more highly integrated, sufficient conductivity cannot be ensured only with polycrystalline silicon, which is commonly employed in the related art. In this respect, one of the conductor materials that has been studied and developed is a metal silicide material which is a compound of metal and silicon. The metal silicide material has superior conductivity as compared to polycrystalline silicon, and better conductivity can be ensured according to reaction and growth material. The metal silicide material can be employed without significantly changing the general methods of semiconductor manufacturing. In this respect, metal silicide has enjoyed widespread use in recent years.

However, metal silicide materials have different characteristics from those of metal or polycrystalline silicon in some cases. For example, metal silicide is vulnerable to etching material for removing a silicon oxide film that is most frequently used during semiconductor fabrication processes. In the process of manufacturing a semiconductor device in which the metal silicide is used, metal silicide regions are not always properly formed to an appropriate shape. As a result, the growth becomes excessive and forms an irregular shape. It is known that the metal silicide element grows as metal and silicon atom diffuse with each other. If the diffusion progresses beyond a proper time period, the metal silicide can become overgrown into an undesired region. When the metal silicide is overgrown, the metal silicide is overgrown up to the surface or interface of the polycrystalline silicon, thus deteriorating the characteristics of the semiconductor device. For example, in a case where the metal silicide is exposed to an interlayer insulating film or an upper surface of the polycrystalline silicon, it is subject to becoming damaged in subsequent etching or cleaning processes.

### SUMMARY OF THE INVENTION

In a process of manufacturing a semiconductor device using metal silicide, methods are provided to prevent over growth of a metal silicide region at the surface or interface of the polycrystalline silicon, and to prevent the metal silicide region from becoming exposed on the surface.

An object of an exemplary embodiment of the present invention is to provide a semiconductor device, in which even if a metal silicide region is recessed and overgrown, the metal silicide is prevented from becoming exposed at the surface of an interlayer insulating film, and thus widening the resulting contact area.

Another object of an exemplary embodiment of the invention is to provide a method of manufacturing a semiconductor device, in which even if a metal silicide region is recessed and overgrown, the metal silicide is prevented from becoming exposed at the surface of an interlayer insulating film, and thus widening the resulting contact area.

Objects of the present invention are not limited to those mentioned above, and other objects of the present invention will be apparently understood by those skilled in the art through the following description.

In order to achieve the above objects, according to an aspect of the present invention, there is provided a semiconductor device including: isolation regions formed on a substrate; source/drain regions in the substrate between the isolation regions; a first interlayer insulating film on the substrate, the isolation regions and the source/drain regions; contact pads vertically penetrating the first interlayer insulating film and electrically connected to the source/drain regions; a second interlayer insulating film on the first interlayer insulating film and the contact pads; a metal silicide region selectively formed on the contact pads at a vertical position that is lower than an upper surface of the first interlayer insulating film; and a contact plug vertically penetrating the second interlayer insulating film and electrically connected to the metal silicide region.

In one embodiment, a contact part where the contact plug is electrically connected to the metal silicide can have a rounded shape.

In another embodiment, a maximum width of the contact part in a horizontal direction is greater than a width of the contact portion of the contact pad.

In another embodiment, a maximum width of the contact part in a horizontal direction is less than a maximum width of the surface of the contact pad.

In another embodiment, the upper surface of the contact pad is formed in a concave shape.

In another embodiment, the metal silicide region has a W-shaped longitudinal section.

In another embodiment, the semiconductor device further comprises a barrier layer between the contact plug and the second interlayer insulating film.

In another embodiment, the semiconductor device further comprises a liner film at an interface between the first interlayer insulating film and the second interlayer insulating film.

In another aspect, a method of manufacturing a semiconductor device comprises: forming isolation regions on a substrate; forming source/drain regions in the substrate between the isolation regions; forming a first interlayer insulating film on the surface of the substrate, the isolation regions and the source/drain regions; forming contact pads vertically penetrating the first interlayer insulating film and electrically connected to the source/drain regions; forming a second interlayer insulating film on the first interlayer insulating film and the contact pads; forming a metal silicide layer on upper portions of one or more of the contact pads at a vertical position that is lower than an upper surface of the first interlayer insulating film; forming a contact plug vertically penetrating the second interlayer insulating film and electrically connected to the metal silicide layer; and forming a signal transmitting line on the second interlayer insulating film that is electrically connected to the contact plug.

In one embodiment, a contact part where the contact plug is electrically connected to the metal silicide is formed in a rounded shape.

In another embodiment, a maximum width of the contact part in a horizontal direction is greater than a width of the contact portion of the contact pad.

In another embodiment, a maximum width of the contact part in the horizontal direction is less than a maximum width of the surface of the contact pad.

In another embodiment, the upper surface of the contact pad is formed in a concave shape.

In another embodiment, the metal silicide region has a W-shaped longitudinal section.

In another embodiment, the method further comprises forming a barrier layer between the contact plug and the second interlayer insulating film.

In another embodiment, the method further comprises forming a liner film on the interface between the first interlayer insulating film and the second interlayer insulating film.

In another aspect, a method of manufacturing a semiconductor device comprises: forming isolation regions on a substrate; forming source/drain regions in the substrate between the isolation regions; forming a first interlayer insulating film on the surface of the substrate, the isolation regions and the source/drain regions; forming contact pads vertically penetrating the first interlayer insulating film and electrically connected to the source/drain regions; forming a second interlayer insulating film on the first interlayer insulating film and the contact pads; forming a contact hole vertically penetrating the second interlayer insulating film and exposing one or more upper surfaces of the contact pads; forming a first spacer at a side wall of the contact hole; forming a void region that exposes lateral surfaces of the first interlayer insulating film by removing the exposed upper portion of the contact pad so as to recess the upper surface of the contact pad; expanding a size of the void region by partially removing the exposed first interlayer insulating film; reducing a size of the void region by forming the second spacer on the surface of the first spacer; forming a metal silicide region on the recessed upper portion of the contact pad; reducing the first and second spacers formed at the side wall of the contact hole; forming a barrier layer at the side wall of the contact hole; forming a contact plug by filling the contact hole with conductive materials; and forming a signal transmitting line on the second interlayer insulating film that is electrically connected to the contact plug.

In one embodiment, the method further comprises planarizing an upper surface of the first interlayer insulating film and the contact pads, before forming the second interlayer insulating film.

In another embodiment, the metal silicide region is formed by forming a metal layer using electroless plating on the upper portion of the contact pad and thermally treating the metal layer.

In another embodiment, the metal silicide region is formed by further forming a stabilization metal layer on the silicide metal layer and thermally treating the stabilization metal layer.

### BRIEF DESCRIPTION OF THE DRAWINGS

The above and other features and advantages of the embodiments of the present disclosure will become more apparent by describing in detail preferred embodiments thereof with reference to the attached drawings in which:

FIGS. 1A to 1E are longitudinal cross-sectional views schematically illustrating semiconductor devices according to preferred embodiments of the invention;

FIGS. 2A to 2H are longitudinal cross-sectional views illustrating a method of manufacturing a semiconductor device according to a first embodiment of the invention;

FIGS. 3A to 3B are longitudinal cross-sectional views illustrating a method of manufacturing a semiconductor device according to a second embodiment of the invention;

FIG. 4 is a view illustrating a process of forming a second liner film on a second interlayer insulating film in the semiconductor device according to a second embodiment of the invention; and

FIGS. 5A to 5B are views illustrating a semiconductor device according to a third embodiment of the invention.

### DETAILED DESCRIPTION OF EMBODIMENTS

Advantages and features of the embodiments of the present invention and methods of accomplishing the same may be understood more readily by reference to the following detailed description of preferred embodiments and the accompanying drawings. The present invention may, however, be embodied in many different forms and should not be construed as being limited to the embodiments set forth herein. Rather, these embodiments are provided so that this disclosure will be thorough and complete. The size and relative size of layers and regions in the drawings are exaggerated for clear description. Like reference numerals refer to like elements throughout the specification.

Embodiments to be described throughout the specification will be explained with reference to the accompanying ideal exemplary drawings that include plan views and cross-sectional views. Therefore, the exemplary drawings may be modified by the manufacturing techniques and/or tolerances. Therefore, the embodiments of the present invention are not limited to the accompanying drawings, and can include modifications to be generated according to manufacturing processes. Therefore, regions exemplified in the drawings have schematic characteristics, and the shape of the regions is an example for specifying regions of elements, and not for narrowing the scope of the invention.

Hereinafter, semiconductor devices according to various embodiments of the invention and a method of manufacturing the same will be described with reference to the accompanying drawings.

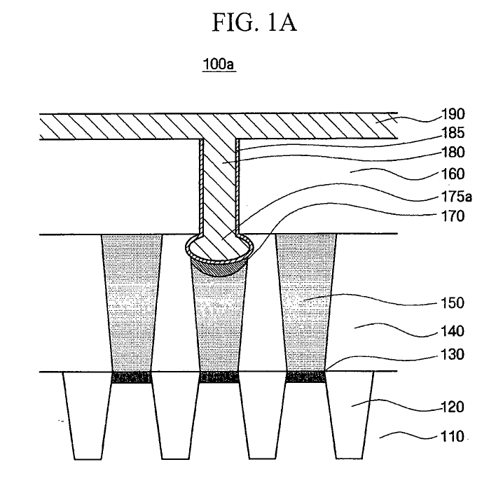

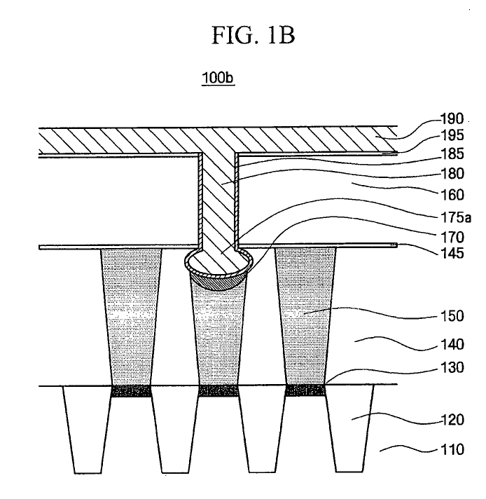

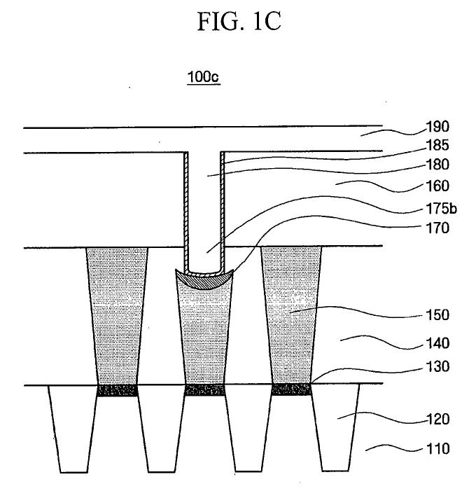

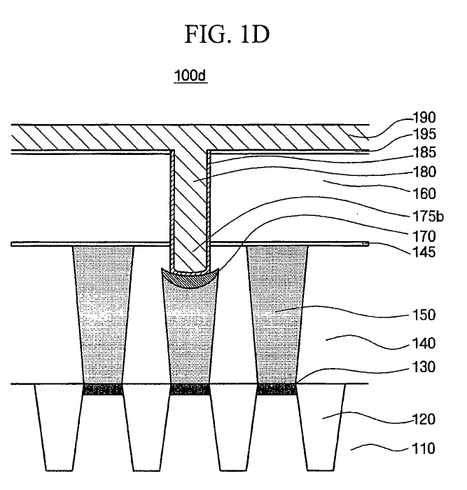

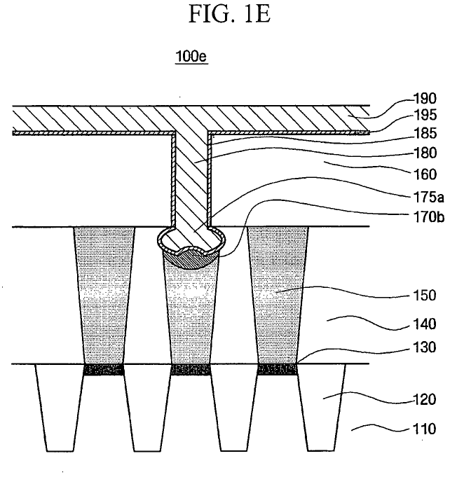

FIGS. 1A to 1E are longitudinal cross-sectional views schematically illustrating semiconductor devices according to the embodiments of the invention.

FIG. 1A is a longitudinal cross-sectional view schematically illustrating a semiconductor device according to a first embodiment of the invention.

Referring to FIG. 1A, a semiconductor device 100a according to the first embodiment of the invention includes isolation regions 120, source/drain regions 130, a first interlayer insulating film 140, contact pads 150, a metal silicide region 170, a second interlayer insulating film 160, a contact plug 180, and a signal transmitting line 190.

The isolation regions 120 are formed in a substrate 110. The source/drain regions 130 are provided at the surface of the substrate 110 between the isolation regions 120. The first interlayer insulating film 140 is formed on the substrate 110. The contact pads 150 vertically penetrate the first interlayer insulating film 140 so as to be electrically connected to the source/drain regions 130. The metal silicide region 170 is formed on the upper end portion of one or more contact pads 150. The second interlayer insulating film 160 is formed on the first interlayer insulating film 140 and the contact pads 150. The contact plug 180 is formed to vertically penetrate the second interlayer insulating film 160 so as to be electrically connected to the metal silicide region 170. The signal transmitting line 190 is formed to electrically connect the contact plug 180, and lies on the second interlayer insulating film 160.

The metal silicide region 170 may be formed in a lower position relative to the upper surface of the first interlayer insulating film 140. In particular, the metal silicide region 170 may be formed at a recessed, lower, position which is spaced apart from the surface of the first interlayer insulating film 140 by a predetermined interval. In the space of the predetermined interval between the metal silicide region 170 and the surface of the first interlayer insulating film 140, a contact part 175a between the contact pad 150 and the contact plug 180 may be formed.

The contact part 175a between the contact pad 150 and the contact plug 180 may be formed in a spherical, semispherical, or otherwise curved, shape, an outer periphery of which is rounded. The lower side of the contact part 175a can be in contact with the upper side of the metal silicide region 170. In other words, the contact part 175a between the contact plug 180 and the metal silicide region 170 may be formed in a curved shape, a periphery of which is rounded.

In addition, the upper surface of the contact pad 150 may be formed in a concave shape. Therefore, the metal silicide region 170 can be concave at a central portion thereof. However, because the metal silicide region 170 is formed by forming a metal layer on the contact pad 150 and thermally treating the metal layer, the metal silicide region 170 may optionally be formed in a convex shape at the center in accordance with the degree of silicidation of the metal layer. In this case, the contact pad 150 and the metal silicide region 170 may be formed in an uneven shape having a convex center portion and outer portion and a concave portion between the center portions and the outer portion. That is, a W-shape is generally shown in the longitudinal cross-sectional view, and a concentric shape is generally shown in the top view.

The isolation regions 120 may be formed by a STI (shallow trench isolation) in the present embodiment.

The source/drain regions 130 may be formed between the isolation regions 120 adjacent to the surface of the substrate 110. In general, the source/drain regions 130 can, for example, be regions that are formed by implanting atoms of group 3 or group 5 on the periodic table therein as an ion state to make the substrate 110 have conductivity. Otherwise, the source/drain regions 130 may comprise a silicidated region. A method of forming the source/drain regions 130 in which ions are implanted and a method of forming the silicidated source/drain regions 130 will be described later. According to the present embodiment, the source/drain regions 130 are exemplified as source/drain regions 130 in which ions are implanted. In the case of the silicidated source/drain regions 130, the contact pads 150 can be formed of metal.

The contact pads 150 are electrically connected to the source/drain regions of the substrate 110 in the present embodiment, but these are not limited but rather illustrative. In other embodiments, the contact pads 150 may be electrically connected to a transistor, a capacitor, other horizontally conductive lines or other elements of the semiconductor device. The contact pads 150 are exemplified and illustrated as comprising polycrystalline silicon having conductivity in the present embodiment. The contact pads 150 are formed into a polycrystalline state by thermally treating amorphous silicon and implanting atoms of group 3 or group 5 on the periodic table therein as an ion state to make the contact pad have conductivity. A method of forming the contact pad 150 will be described below.

According to the present embodiment, the first interlayer insulating film 140 and the second interlayer insulating film 160 are formed of silicon oxide. Materials for the first and second interlayer insulating films 140 and 160 and a method for forming them will be described below.

The contact plug 180 vertically penetrating the second interlayer insulating film 160 and electrically connected to the contact pad 150 may be formed. Since the metal silicide region 170 is formed at the upper end portion of the contact pad 150, the contact plug 180 can be electrically connected to the metal silicide region 170.

A barrier layer 185 may be formed on the interface around the contact plug 180. The barrier layer 185 may be formed, respectively, on the interface between the contact plug 180 and the second interlayer insulating film 160, on the interface between the contact plug 180 and the first interlayer insulating film 140, and on the interface between the contact plug 180 and the metal silicide region 170. According to the present embodiment, the barrier layer 185 is not formed at portions of the interface between the contact plug 180 and the metal silicide region 170. This may result from the process of forming the barrier layer where the barrier layer is partially removed. To better understand the methods of the embodiments of the present invention, for illustration in the drawing, the barrier layer 185 is illustrated as being present at the interface between the contact plug 180 and the metal silicide region 170.

The contact plug 180 may be electrically connected to the signal transmitting line 190 which is formed on the second interlayer insulating film 160, the signal transmitting line 190 may be formed of wire line for transmitting electrical signals in a horizontal direction. In another embodiment, the signal transmitting line may be connected to a lower electrode of a storage capacitor.

In the semiconductor device 100a according to the first embodiment of the invention shown in FIG. 1A, because the metal silicide regions 170 are formed at a position that is lower than, or recessed from, the upper surface of the first interlayer insulating film 140, the metal silicide region 170 is not exposed to the surface of first interlayer insulating film 140, even in a case where silicidation is excessive. Therefore, the metal silicide region 170 is prevented from experiencing external physical and chemical damage in subsequent fabrication processes.

Because the contact part 175a between the contact plug 180 and the metal silicide region 170 is formed in a curved, semispherical, spherical shape, the contact area is widened, thus decreasing contact resistance. The maximum width in the horizontal direction of the contact part 175a is larger than the width of a lower end portion of the body of the contact plug 180.

FIG. 1B is a longitudinal cross-sectional view schematically illustrating a semiconductor device 100b according to a second embodiment of the invention Referring to FIG. 1B, the semiconductor device 100b is different from the semiconductor device 100a according to the first embodiment of the invention exemplified in FIG. 1A in that a first liner film 145 is formed at the interface between the first interlayer insulating film 140 and the second interlayer insulating film 160.

According to the second embodiment, the first liner film 145 may be formed, in one embodiment, of silicon nitride. The first liner film 145 operates to prevent the metal silicide region 170 from being exposed to the surface of the first interlayer insulating film 140, even in a case where the metal silicide region 170 is overgrown. According to the embodiments, since the metal silicide region 170 is formed at a position lower than the surface of the first interlayer insulating film 140, the metal silicide regions 170 are prevented from being exposed to the lower surface of the first interlayer insulating film 140. Further, even when the metal silicide region 170 is erroneously formed at a position higher than a desired position, in rare cases, the first liner film 145 can prevent the overgrown metal silicide region 170 from being exposed to the lower surface of the first interlayer insulating film 140.

A second liner film 195 may be formed at the interface between the second interlayer insulating film 160 and signal transmitting line 190. The second liner film 195 operates to isolate the signal transmitting line 190 from insulating materials, when the signal transmitting line 190 is formed of metal. The second liner film 195 may be formed of insulating materials such as silicon nitride, or conductive materials such as metal. When the second liner film 195 is formed of metal, it can be formed of a Ti/TiN film, for example. When the signal transmitting line 190 is copper, the second liner film 195 can be formed of a Ta/TaN film. When the second liner film 195 is formed of metal, the second liner film 195 and the barrier layer 185 can be concurrently formed. That is, they may be formed of the same material. Therefore, even though the second liner film 195 and the barrier layer 185 are illustrated by different reference numerals and distinguished by hatching in the drawing, they may have the same reference numeral and the same hatching.

FIG. 1C is a longitudinal cross-sectional view schematically illustrating a semiconductor device 100c according to a third embodiment of the invention.

Referring to FIG. 1C, the semiconductor device according to the third embodiment of the invention is different from the semiconductor device according to the first embodiment of the invention shown in FIG. 1A in that a contact part 175b between the contact plug 180 and the metal silicide region 170 is formed so as to have smaller contact area with the upper surface metal silicide region 170 rather than make contact with the entire area thereof. In other words, the contact part 175b may be formed in a generally rounded shape in the vertical direction, but it may also be formed in a shape imitating the shape of a contact hole 180. Accordingly, it should be understood that the barrier layer 185 may also be formed in a rounded shape.

According to the third embodiment, the above-described shape of the contact part 175b requires less time to be formed than the amount of time to perform the process of forming the semiconductor device 100a according to the first embodiment of the invention shown in FIG. 1A. If the process is not performed stably when the contact part 175b is formed in the first embodiment, a void or the like is likely to be formed at a lower portion of the second interlayer insulating film 160. In this case, according to the third embodiment of the invention, it is possible to prevent the formation of the void. In addition, according to the third embodiment, the process of forming the barrier layer 185 may be more reliably performed. That is, when the contact part 175b between the contact plug 180 and the metal silicide region 170 is formed to have the above-described shape according to the third embodiment, the process of forming the contact part 175b can be performed with greater reliability.

FIG. 1D is a longitudinal cross-sectional view schematically illustrating a semiconductor device according to a fourth embodiment of the invention.

Referring to FIG. 1D, the semiconductor device according to the fourth embodiment is different from the semiconductor device according to the third embodiment of the invention shown in FIG. 1C in that a first liner film 145 is formed on the interface between the first interlayer insulating film 140 and the second interlayer insulating film 160.

According to the fourth embodiment, the first liner film 145 may be formed of silicon nitride. The first liner film 145 operates to prevent the metal silicide region 170 from being exposed to the lower surface of the first interlayer insulating film 140 even in a case where the metal silicide region 170 is overgrown. According to the embodiments, because the metal silicide region 170 is formed at a lower position than the surface of the first interlayer insulating film 140, the metal silicide regions 170 are prevented from being exposed to the lower surface of the first interlayer insulating film 140. Further, even when the metal silicide region 170 is erroneously formed at a position higher than a desired position, in rare cases, the first liner film 145 can prevent the overgrown metal silicide region 170 from being exposed to the lower surface of the first interlayer insulating film 140.

The second liner film 195 may be formed on the interface between the second interlayer insulating film 160 and the signal transmitting line 190. The second liner film 195 operates to isolate the signal transmitting line 190 from insulating materials, when the signal transmitting line 190 is formed of metal. The second liner film 195 may be formed of insulating materials such as silicon nitride, or conductive materials such as metal. When the second liner film 195 is formed of metal, the second liner film can comprise a Ti/TiN film, for example. When the signal transmitting line 190 is formed of copper, the second liner film can comprise a Ta/TaN film. When the second liner film 195 is formed of metal, the second liner film 195 and the barrier layer 185 can be concurrently formed. That is, they may be formed of the same material. Therefore, even though the second liner film 195 and the barrier layer 185 are illustrated by different reference numerals and distinguished by hatching in the drawing, they may have the same reference numeral and the same hatching.

According to the embodiments, the lateral lobes of the contact part 175a that extend in a lateral direction may be a region which is obtained by removing the first interlayer insulating film 140 and filling the insulating film therein again, as will be described in further detail below.

FIG. 1E is a longitudinal cross-sectional view schematically illustrating a semiconductor device 100e according to a fifth embodiment of the invention.

Referring to FIG. 1E, in the semiconductor device 100e according to the fifth embodiment of the invention, a metal silicide region 170b is formed such that the center portion and the outer portions protrude in an upward direction.

FIG. 1E illustrates that the metal silicide region 170b is formed in various shapes in accordance with a method of formation or conditions of the process, when the metal silicide region 170b is formed. Therefore, it will be apparently understood by those skilled in the art that the metal silicide region 170 may be formed in various shapes, such as an upwardly convex shape, a downwardly concave shape, or an uneven shape, which correspond to various conditions during the process of silicidation. All of the above-described embodiments in which the metal silicide regions 170 and 170b are formed in various shapes fall under the scope of the present invention.

Next, the method of manufacturing the semiconductor devices according to the embodiments of the invention will be described with reference to the accompanying drawings.

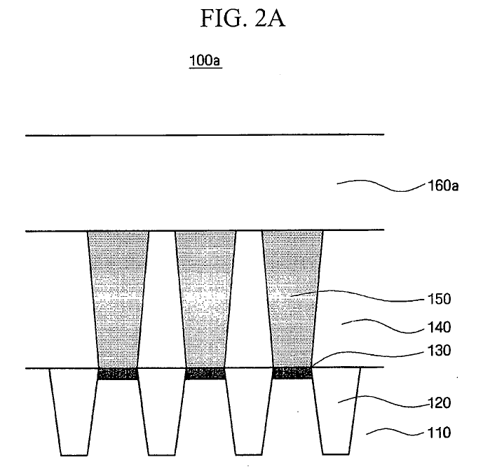

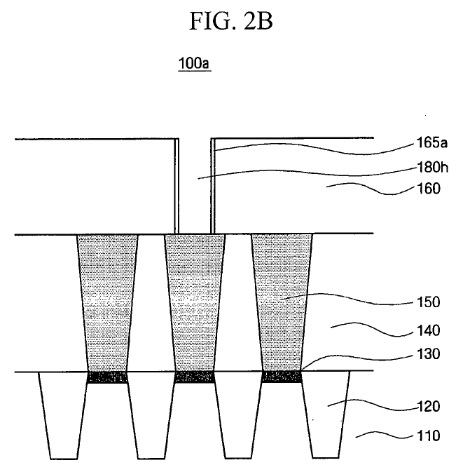

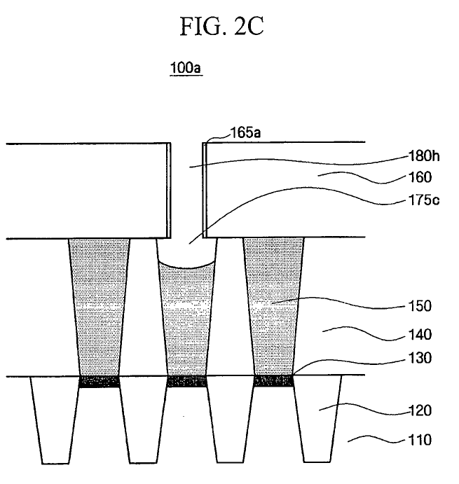

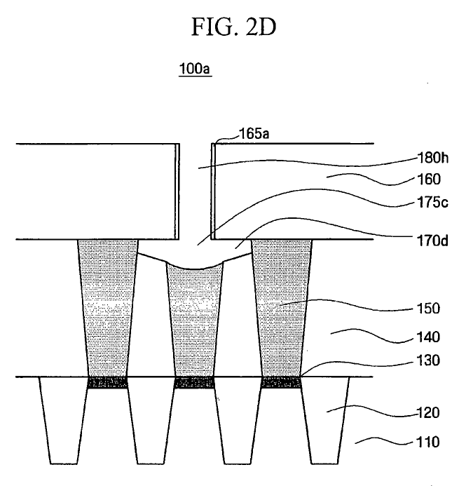

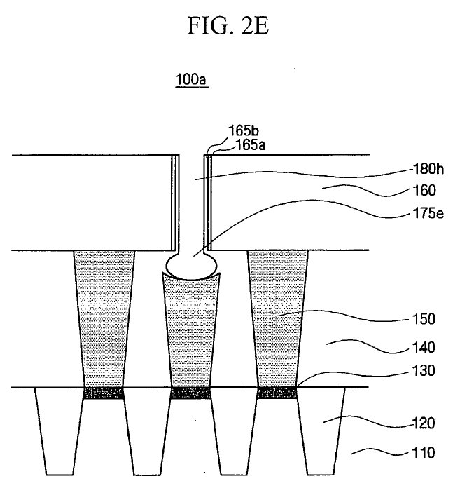

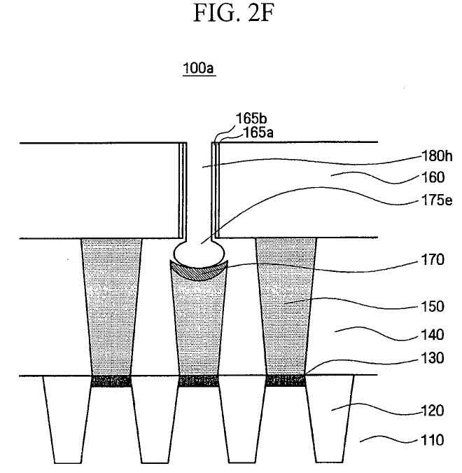

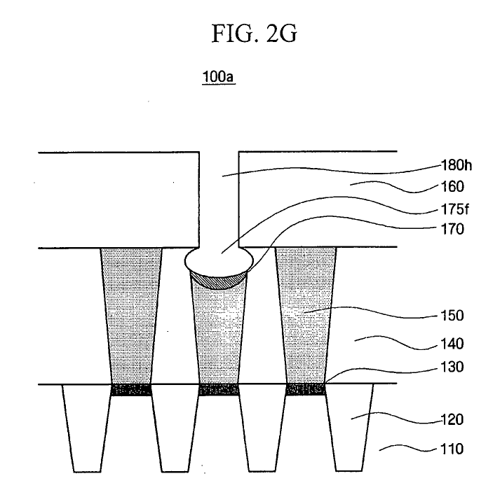

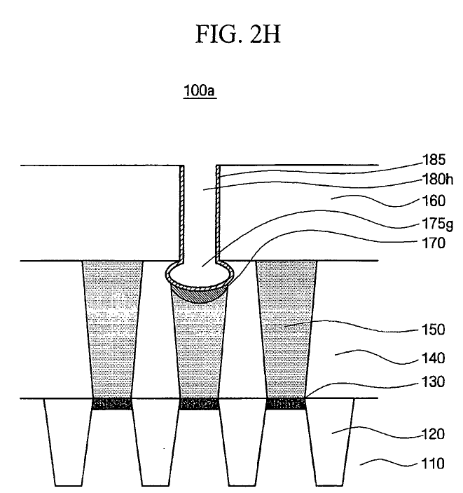

FIGS. 2A to 2H are longitudinal cross-sectional views illustrating the method of manufacturing the semiconductor device according to the first embodiment of the invention.

Referring to FIG. 2A, isolation regions 120 are formed in the substrate 110. Source/drain regions 130 are formed between the isolation regions 120 adjacent to the surface of the substrate 110. The first interlayer insulating film 140 is formed on the entire surface of the isolation regions 120 and the substrate 110. The contact pad 150 vertically penetrating the first interlayer insulating film 140 and electrically connected to the source/drain regions 130 is formed. The second interlayer insulating film 160 is formed on the first interlayer insulating film 140 and the contact pads 150.

The substrate 110 is of a type that can be used for manufacturing a semiconductor device, and may comprise, for example, a silicon substrate, a silicon-germanium substrate, an SOI substrate, an SOS substrate or the like. According to the first embodiment, for the purpose of illustration, the substrate 110 is a silicon substrate.

The isolation regions 120 are exemplified using STI (Shallow Trench Isolation) in the first embodiment. Since a method of forming the isolation regions 120 by STI is a well known technique, detailed description thereof will be omitted.

The source/drain regions 130 may be regions that are obtained by implanting atoms of group 3 or group 5 of the periodic table therein as an ion state to make the substrate 110 have conductivity. The source/drain regions 130 may be divided into N type or P type, and in the case of N type, P or As ions are implanted so as to provide conductivity. In the case of P type, B ions are implanted so as to provide conductivity. According to the present embodiment, the source/drain regions 130 may be N type. Since a method of forming NMOS including N type source/drain regions and PMOS including P type source drain regions is well known to those skilled in the art, detailed description will be omitted.

Otherwise, the source/drain regions 130 may comprise silicidated source/drain regions. The silicidated source/drain regions 130 can be formed by forming a metal layer on the substrate 110 having a thickness in the range of 200 to 500 Å, and thermally treating the metal layer at the temperature of several hundreds ° C., and causing silicon atoms and metal atoms to combine with each other. A method of forming the metal layer on the substrate 110 may be performed by a sputtering which is one of the physical deposition methods, or by plating. In particular, in the case of plating, electroless plating is used. According to the present embodiment, the metal silicide region 170 may be formed by using nickel, cobalt, titanium, or tungsten as silicide metal. In the case of forming the silicide region, the silicide region may be formed by forming a metal layer for silicide, and forming another metal layer on the metal layer to make the silicide region stable. For example, metal such as platinum or tantalum is further formed on the metal layer for silicide, and is thermally treated so as to form a silicide region. Metallic materials for making the silicide region stable may be formed of 10 to 50 atom % of silicide metal. The reason for forming the material as atom % is that because each of the metallic materials has a different distance between atoms, the material is formed not by comparing the thickness of the metal layers but is formed as atom proportion to help the metal layers chemically combine with each other. In the case of using sputtering, the metal layer may be formed on the silicide metal by sputtering. In the case of using electroless plating, the metal layer is formed as a stabilization metal is included in plating solution. In particular, when a nickel silicide region is formed by using nickel, the silicide metal forms a nickel layer, and a metal layer for stabilization is formed on the nickel layer in the form of Ni-alloy, and then silicidation proceeds, thereby forming the nickel silicide layer. A metal layer for alloy which is used in Ni-alloy may be formed of 10 to 50 atom %, as compared to nickel. Although not described in the specification, experiments are performed under the condition that the stabilization metal layer is formed of 30 atom % of the silicide metal, and the metal for alloy is also formed of 30 atom %, as compared to nickel. Therefore, satisfactory results can be obtained.

Next, the first interlayer insulating film 140 is formed on the entire surface of the substrate 110. That is, the first interlayer insulating film 140 is formed on the isolation regions 120 and the source/drain regions 130 on the substrate 110. The first interlayer insulating film 140 may be formed of silicon oxides having superior planarization characteristics. For example, the first interlayer insulating film 140 may be formed of USG, BSG, PSG, BPSG, SOG, PE-TEOS Oxide, HDP Oxide, HSQ, etc. Otherwise, more various silicon oxides, such as TOSZ and HARP (product brand) can be used. The method of forming the first interlayer insulating film 140 may be different according to the kind of silicon oxides. For example, USG, BSG, PSG, BPSG, etc. can be formed by a spin coating method or a deposition method. PE-TEOS Oxide and HDP-Oxide can be formed by using a plasma deposition method. Other available various silicon oxides and a method forming the same are well known to those skilled in the art, thus detailed description thereof will be omitted.

Next, the contact pads 150 vertically penetrating the first interlayer insulating film 140 and electrically connected to the source/drain regions 130 are formed. According to the present embodiment, the contact pads 150 may be formed of polycrystalline silicon. The contact pads 150 are formed by the forming first contact hole 180h, and filling the first interlayer insulating film 140 and the first contact hole 180h with polycrystalline silicon therein, and performing planarization such as CMP on the entire surface.

In this case, a first liner film (not shown) may be formed on the first interlayer insulating film 140. The first liner film will be described below.

Next, the second interlayer insulating film 160 is formed on the entire surface of the first interlayer insulating film 140 and the contact pad 150. In forming the second interlayer insulating film 160, materials of the first interlayer insulating film 140 and the method of forming the first interlayer insulating film 140 can be employed.

In this case, a second liner (not shown) may be formed on the second interlayer insulating film 160. The second liner may be formed of an insulating film using silicon nitride or silicon oxidized nitrides or the like.

Referring to FIG. 2B, a second contact hole 180h vertically penetrating the second interlayer insulating film 160 and exposing one or more contact pads 150 is formed, and a first spacer 165a is formed at a side wall of the second contact hole 180h. According to the present embodiment, the first spacer 165a can comprise, for example, silicon nitride. According to the present embodiment, for illustration, only one second contact hole 180h is formed in the drawing. This illustration is only for clear understanding of the principles of the embodiments of the invention. Actually, a plurality of such contact plugs 180 can be formed and a cross-sectional view of adjacent contact plugs 180 can be seen. Throughout the specification, a single, rather than multiple, contact plugs 180 are shown in the drawings, to simply the drawings and to provide a clear understanding of the embodiments of the present invention.

In the example drawing of FIG. 2B, nothing is formed on the second interlayer insulating film 160. In an embodiment not shown, the first spacer 165a may be formed to extend onto the second interlayer insulating film 160. The first spacer 165a can be initially formed on the exposed upper surface of the contact pad 150, and the first spacer 165a is then removed therefrom. As a result, the upper surface of the contact pad 150 is exposed.

Referring to FIG. 2C, a space or void 175c is formed by removing the exposed upper portion of the contact pad 150. According to the present embodiment, the space 175c where the upper portion of the contact pad 150 is removed may be formed by an isotropic etching method. For example, the upper portion of the contact pad 150 can be removed by a selective wet etching process so as to form the space 175c. As a result, the upper surface of the remaining contact pad 150 has a rounded shape.

A method of wet-etching polycrystalline silicon is well known to those skilled in the art, detailed description will be omitted.

Referring to FIG. 2D, a portion 170d of the first interlayer insulating film 140, which is exposed to the space 175c where the upper portion of the contact pad 150 is removed, is removed. In this case, lateral sides of other adjacent contact pads 150 may be exposed, as illustrated in the drawing; however, the lateral sides of adjacent control pads need not necessarily be exposed. The minimum conditions that satisfy the technical concepts of the present embodiment are that a widened portion of the first interlayer insulating film 140 is removed in the horizontal direction above the upper surface of the contact pad 150. According to the present embodiment, because the interval between the adjacent contact pads 150 is quite small, the removal of a proper amount of the first interlayer insulating film 140 for a predetermined process time is a difficult process to control. Therefore, to provide a more reliable, and more simple to control, process, it is described herein that the technical concepts of the present invention can be achieved even though the lateral side of the adjacent contact pads 150 are exposed.

In addition, according to the embodiments, only one contact pad 150 is exemplified and illustrated in order to better describe the technical concepts of the embodiments of the present invention, but many contact pads 150, or every contact pad 150, can be processed in the same manner. Therefore, since the embodiment in which the lateral sides of the adjacent contact pads 150 are exposed may be understood in such as way that all of the upper portions of the contact pad 150 are removed, thus, it is understood that a wide portion of the first interlayer insulating films 140 are removed beyond the upper surface of the contact pad 150.

Referring to FIG. 2E, a second spacer 165b is formed on the surface of the first spacer 165a. According to the present embodiment, the second spacer 165b may be formed of silicon oxide. In this case, the space 175d where the lateral sides of the adjacent contact pads 150 may have been formerly exposed can be at least partially filled. That is, the space 175e where the upper portion of the contact pad 150 is removed is decreased in size. Also, the upper surface of the contact pad 150 is continuously exposed.

Referring to FIG. 2F, the metal silicide region 170 is formed on the exposed upper portion of the contact pad 150. According to the present embodiment, the metal silicide region 170 is formed by forming a metal layer on the exposed upper surface of the contact pad 150, for example by sputtering or an electroless plating, and by performing silicidation of the metal layer with thermal treatment or the like.

According to the present embodiment, even if silicidation proceeds excessively, the overgrown metal silicide region 170 is prevented from being exposed to the upper surface of the first interlayer insulating film 140. In this respect, the drawing illustrates the general shape of the overgrown metal silicide region 170. That is, the metal silicide region 170 extends across the entire upper surface of the contact pad 150; however, this is not necessary, and the metal silicide region 170 does not need to extend across the entire upper surface of the contact pad 150.

Because the metal silicide region 170 according to the present embodiment is not exposed to the upper surface of the first interlayer insulating film 140 or to the external environment, the metal silicide region 170 is protected from physical and chemical damage during subsequent processes. That is, because the metal silicide region 170 is protected from such exposure, the metal silicide region 170 can maintain a desired area or volume, thereby obtaining low resistance. Moreover, since patterns and intervals do not need to be formed in a large size due to expected damage of the metal silicide region 170, the pattern of the semiconductor device can be designed more precisely, thus enhancing integration.

Referring to FIG. 2G, the first spacer 165a and second spacer 165b are removed. The first spacer 165a and second spacer 165b can be removed by respectively different etching methods. For example, the second spacer 165b is first removed by a wet etching method using a diluted hydrofluoric acid, and the first spacer 165a is then removed by using a diluted phosphoric acid. When the first spacer 165a and second spacer 165b are removed by a wet etching method, the etching may be performed continuously until a subsequent cleaning process. In this case, a space 175f where the upper portion of the contact pad 150 is removed can be increased by as much as the amount of the removed portion of the first spacer.

Referring to FIG. 2H, barrier layer 185 is formed at the side wall of the second contact hole 180h. The barrier layer 185 may be formed on the metal silicide region 170. The barrier layer 185 may be formed of a different material relative to that of the contact plug 180 in the present embodiment. For example, the barrier layer may be formed of a Ti/TiN layer; otherwise, if the contact plug 180 is formed of copper, the barrier layer 185 may be formed of a Ta/TaN layer. In the present illustration, although the barrier layer is not shown as being formed on the second interlayer insulating film 160, in fact, the barrier layer 185 may optionally be formed on the second interlayer insulating film 160.

Next, the contact plug 180 is formed by filling the contact hole 180h with conductive material. According to the present embodiment, the contact plug 180 may be formed of, for example, tungsten, aluminum, copper or other suitable metal or conductive material.

Further, the conductive signal transmitting line 190 may be further formed on the second interlayer insulating film 160. According to the present embodiment, the signal transmitting line 190 may be formed of the same material as the contact plug 180, for example.

By performing the above-described processes, the formation of the semiconductor device according to the embodiment of the invention shown in FIG. 1A is completed.

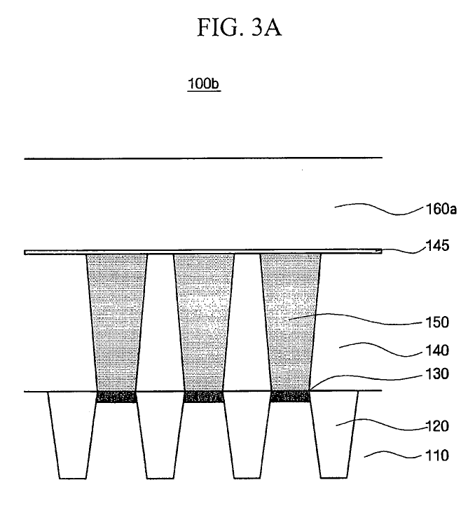

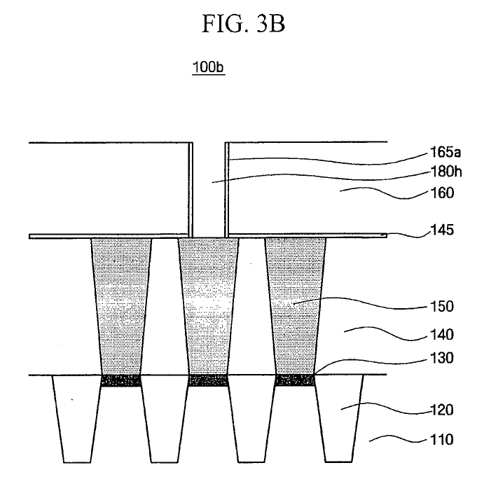

FIGS. 3A to 3B are longitudinal cross-sectional views illustrating a method of manufacturing a semiconductor device according to the second embodiment of the invention.

Referring to FIG. 3A, in the step of FIG. 2A, the first liner film 145 is formed, and more particularly, the first interlayer insulating film 140 and the contact pads 150 are formed and planarized, and then the first liner film 145 is formed on the entire surface of the first interlayer insulating film 140 and the contact pads 150. The first liner film 145 can be formed for example, by a deposition method using silicon nitride as plasma in the present embodiment. Next, the second interlayer insulating film 160 is formed on the first liner film 145.

Referring to FIG. 3B, a second contact hole 180h vertically penetrating the second interlayer insulating film 160 and exposing the upper surface of the contact pad 150 is formed, and the first spacer 165a is formed at the inner wall of the second contact hole 180h. In this case, the first liner film 145 is removed from the exposed upper portion of the contact pad 150, and remains on the upper portion of the contact pad 150 that is not exposed.

The first liner film 145 can prevent the lower portion of the second interlayer insulating film 160 from being damaged by etching solution, in subsequent processes, that is, the process of forming a space by removing the exposed upper portion of the first contact plug 180, and the process of removing the first interlayer insulating film 140 which is exposed through the space. In addition, when the metal silicide region 170 is formed on the upper portion of the contact pad 150, the first liner file 145 can prevent the overgrown metal silicide region 170 from being exposed beyond the surface of the first interlayer insulating film 140. In addition, when the first liner film 145 is formed of silicon nitride, the membrane is denser and harder than silicon oxide; therefore, when the first interlayer insulating film 140 is partially removed along the adjacent contact pads 150, the first liner film 145 can operate to support the second interlayer insulating film 160.

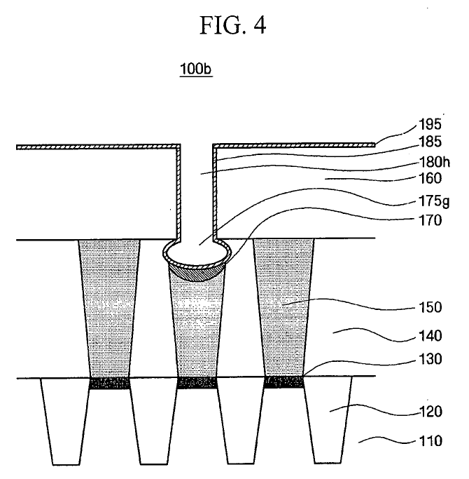

FIG. 4 is a view illustrating a process of forming a second liner 195 film on a second interlayer insulating film 160 in the semiconductor device 100b according to the second embodiment of the invention.

According to the present embodiment, to better understand the concept of the embodiments of the present invention, for illustration in the drawing, the second liner film 195 is formed of the same material as the barrier layer 185. If the second liner film 195 is formed of a material different from the barrier layer 185, for example, if it is formed of a silicon nitride film or other insulating material, the insulating second liner film 195 may be formed after the second interlayer insulating film 160 is formed. However, because the insulating second liner film 195 can be inserted in any of the various processes, the process according to the present embodiment and the description thereof are not limited but illustrative.

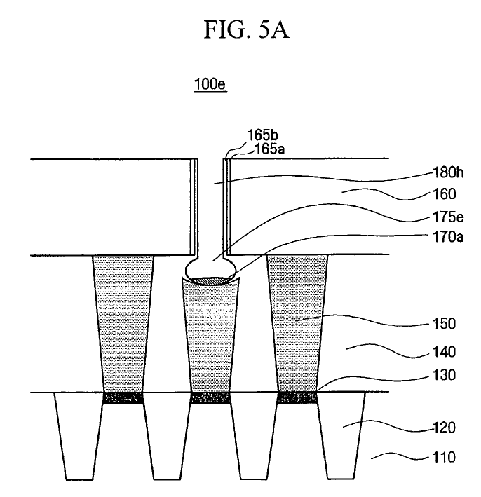

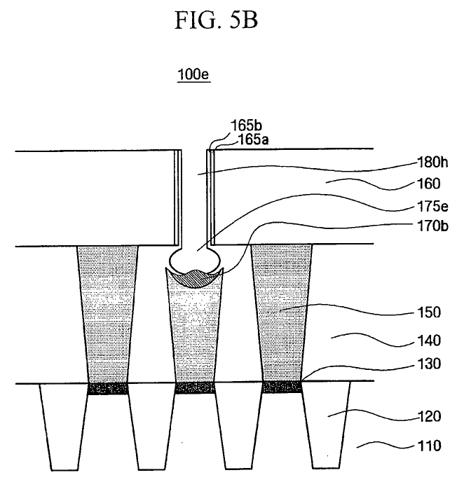

FIGS. 5A to 5B are views illustrating formation of a semiconductor device 100e according to a third embodiment of the invention.

Referring to FIG. 5A, the silicide metal layer 170a is formed on the exposed upper portion of the contact pad 150. According to the present embodiment, the silicide metal layer 170a may be formed by a PVD or electroless plating. In addition, although not shown, a silicidated stabilization metal layer may be further formed on the silicide metal layer 170a, if the silicide metal layer 170a comprises nickel, and an alloy metal layer can further be formed to form a nickel alloy layer.

Referring to FIG. 5B, the metal silicide region 170b is formed by performing silicidation such as thermal treatment. According to the present embodiment, metal silicide region 170b may be formed to have a convex shape at the center. To better understand the concepts of this embodiment of the present invention, the drawing is slightly exaggerated. In fact, in one embodiment, the convex shape at the center can be too slight to recognize. That is, the center is convex, but the surface is relatively flat. As a result, metal silicide region 170b may be formed in an uneven shape having a convex center portion and a convex outer portion. That is, a W-shape is shown in the longitudinal cross-sectional view, but a concentric shape would be shown from a top view.

Although embodiments of the present invention have been described in connection with the exemplary embodiments, it will be apparent to those skilled in the art that various modifications and changes may be made thereto without departing from the scope and spirit of the invention. Therefore, it should be understood that the above embodiments are not limiting, but rather illustrative, in all aspects.

In the semiconductor device according to the embodiments of the invention, because the metal silicide region is formed lower than the surface of the first interlayer insulating film, the metal silicide region is not exposed to the external environment, or such exposure is limited, even if the metal silicide region is overgrown. Therefore, the metal silicide region is protected from external physical and chemical damage. In addition, because the contact region between the contact plugs can be made larger, contact resistance is decreased, which improves the operation of the semiconductor device and reliability.

What is claimed is:

1. A semiconductor device comprising:
isolation regions formed on a substrate;
source/drain regions in the substrate between the isolation regions;
a first interlayer insulating film on the substrate, the isolation regions and the source/drain regions;
contact pads vertically penetrating the first interlayer insulating film and electrically connected to the source/drain regions;
a second interlayer insulating film on the first interlayer insulating film and the contact pads;
a metal silicide region selectively formed on the contact pads at a vertical position that is lower than an upper surface of the first interlayer insulating film; and
a contact plug vertically penetrating the second interlayer insulating film and electrically connected to the metal silicide region.

2. The semiconductor device of claim 1, wherein a contact part where the contact plug is electrically connected to the metal silicide has a rounded shape.

3. The semiconductor device of claim 2, wherein a maximum width of the contact part in a horizontal direction is greater than a width of the contact portion of the contact pad.

4. The semiconductor device of claim 2, wherein a maximum width of the contact part in a horizontal direction is less than a maximum width of the surface of the contact pad.

5. The semiconductor device of claim 1, wherein the upper surface of the contact pad is formed in a concave shape.

6. The semiconductor device of claim 1, wherein the metal silicide region has a W-shaped longitudinal section.

7. The semiconductor device of claim 1, further comprising:
a barrier layer between the contact plug and the second interlayer insulating film.

8. The semiconductor device of claim 1, further comprising:
a liner film at an interface between the first interlayer insulating film and the second interlayer insulating film.

9. A method of manufacturing a semiconductor device, the method comprising:
forming isolation regions on a substrate;
forming source/drain regions in the substrate between the isolation regions;
forming a first interlayer insulating film on the surface of the substrate, the isolation regions and the source/drain regions;
forming contact pads vertically penetrating the first interlayer insulating film and electrically connected to the source/drain regions;
forming a second interlayer insulating film on the first interlayer insulating film and the contact pads;
forming a metal silicide layer on upper portions of one or more of the contact pads at a vertical position that is lower than an upper surface of the first interlayer insulating film;
forming a contact plug vertically penetrating the second interlayer insulating film and electrically connected to the metal silicide layer; and
forming a signal transmitting line on the second interlayer insulating film that is electrically connected to the contact plug.

10. The method of claim 9, wherein a contact part where the contact plug is electrically connected to the metal silicide is formed in a rounded shape.

11. The method of claim 10, wherein a maximum width of the contact part in a horizontal direction is greater than a width of the contact portion of the contact pad.

12. The method of claim 10, wherein a maximum width of the contact part in the horizontal direction is less than a maximum width of the surface of the contact pad.

13. The method of claim 9, wherein the upper surface of the contact pad is formed in a concave shape.

14. The method of claim 9, wherein the metal silicide region has a W-shaped longitudinal section.

15. The method of claim 9, further comprising forming a barrier layer between the contact plug and the second interlayer insulating film.

16. The method of claim 9, further comprising forming a liner film on the interface between the first interlayer insulating film and the second interlayer insulating film.

17. A method of manufacturing a semiconductor device, the method comprising:
forming isolation regions on a substrate;
forming source/drain regions in the substrate between the isolation regions;
forming a first interlayer insulating film on the surface of the substrate, the isolation regions and the source/drain regions;
forming contact pads vertically penetrating the first interlayer insulating film and electrically connected to the source/drain regions;
forming a second interlayer insulating film on the first interlayer insulating film and the contact pads;
forming a contact hole vertically penetrating the second interlayer insulating film and exposing one or more upper surfaces of the contact pads;
forming a first spacer at a side wall of the contact hole;
forming a void region that exposes lateral surfaces of the first interlayer insulating film by removing the exposed upper portion of the contact pad so as to recess the upper surface of the contact pad;
expanding a size of the void region by partially removing the exposed first interlayer insulating film;
reducing a size of the void region by forming the second spacer on the surface of the first spacer;
forming a metal silicide region on the recessed upper portion of the contact pad;
reducing the first and second spacers formed at the side wall of the contact hole;
forming a barrier layer at the side wall of the contact hole;
forming a contact plug by filling the contact hole with conductive materials; and
forming a signal transmitting line on the second interlayer insulating film that is electrically connected to the contact plug.

18. The method of claim 17, further comprising:
planarizing an upper surface of the first interlayer insulating film and the contact pads, before forming the second interlayer insulating film.

19. The method of claim 17, wherein the metal silicide region is formed by forming a metal layer using electroless plating on the upper portion of the contact pad and thermally treating the metal layer.

20. The method of claim 19, wherein the metal silicide region is formed by further forming a stabilization metal layer on the silicide metal layer and thermally treating the stabilization metal layer.
